(19) United States
(12) Patent Application Publication
(10) Pub. No.: US 2023/0411262 A1
(43) Pub. Date: Dec. 21, 2023

(54) MICROELECTRONICS DEVICE PACKAGE AND METHODS

(71) Applicant: Texas Instruments Incorporated, Dallas, TX (US)

(72) Inventors: Osvaldo Lopez, Annadale, NJ (US); Jonathan Noquil, Plano, TX (US); Jose Carlos Arroyo, Allen, TX (US); Makarand R. Kulkarni, Plano, TX (US); Guangxu Li, Allen, TX (US)

(21) Appl. No.: 18/335,979

(22) Filed: Jun. 15, 2023

Related U.S. Application Data
(60) Provisional application No. 63/352,566, filed on Jun. 15, 2022.

(51) Int. Cl. H01L 23/498; H01L 21/56

(52) U.S. Cl. CPC H01L 23/49811; H01L 21/565; H01L 2021/60022; H01L 23/49822; H01L 21/563

(57) ABSTRACT

An example microelectronics device package includes: a device mounting layer on an uppermost trace conductor layer on a device side surface of a package substrate, the uppermost trace conductor layer having a first pattern density. The device mounting layer includes a device connection conductor layer; a device mounting land conductor layer on the device connection conductor layer, the device mounting land conductor layer having device mounting land conductors directly contacting the conductors of the device connection conductor layer and having a second pattern density that is less than the first pattern density. A semiconductor die is flip chip mounted to the device mounting layer by solder joints between post connects extending from the semiconductor die and the device mounting land conductors. Mold compound covers the semiconductor die, and the device mounting layer, the mold compound is spaced from the uppermost trace conductor layer by the device mounting layer.

### CROSS-REFERENCE TO RELATED APPLICATIONS

This application claims the benefit of and priority to U.S. Provisional Application No. 63/352,566 filed Jun. 15, 2022, which Application is hereby incorporated herein by reference in its entirety.

### TECHNICAL FIELD

This disclosure relates generally to microelectronics device packages, and more particularly to microelectronics device packages including one or more semiconductor dies coupled to package terminals by conductors in a package substrate.

### BACKGROUND

Processes for producing semiconductor device packages include mounting a semiconductor die and sometimes additional components to a package substrate, and covering the electronic devices with a dielectric material such as a mold compound to form packaged devices. In one approach, a multilayer package substrate with conductors in dielectric material and having terminals on a board side surface is used to mount a semiconductor die in a flip chip die mount. In some examples additional components are included in the semiconductor device package, such as passive components. Flip chip mounted semiconductor dies feature conductive post connects extending from bond pads on a device side surface of the semiconductor dies. The conductive post connects end in a solder ball or solder bump. The conductive post connects can be made of copper, and can be shaped as a column or pillar, the copper post connects are sometimes referred to as “copper pillars” or “copper pillar bumps” when the solder is included.

In an example approach, a semiconductor die is mounted on a multilayer package substrate by positioning the solder to contact conductors exposed on a device side surface of the multilayer package substrate, and performing solder reflow to mechanically connect the conductive post connects to the multilayer package substrate. The multilayer package substrate provides signal routing and portions of the conductors on a board side surface of the multilayer package substrate can form terminals for the microelectronics device package. In addition to the semiconductor die or dies, passive components used in forming a circuit topology with the semiconductor die or dies can be surface mounted to the conductors of the multilayer package substrate by solder mounting the passives to the device side surface of the multilayer package substrate.

When integrating semiconductor dies and passive components to form power circuit devices, such as power converters, the currents carried by the conductors of the package substrate can exceed several amperes, and be up to tens or even hundreds of amperes. In one example, a power semiconductor device includes a semiconductor die configured to carry over one hundred amperes at a switch node, and passive components are coupled to the switch node. The conductors in the multilayer package substrate are configured to provide low resistance current carrying paths, and can be quite large. These conductors are exposed on the device side surface of the multilayer package substrate.

A molding process then covers the semiconductor die, the conductive post connects and portions of the multilayer package substrate with mold compound. Portions of the conductors that form terminals are exposed from the mold compound for mounting the microelectronics device package to a system board. Increasingly “no-lead” packages are used, where the terminals are coextensive with the body of the microelectronics device package, and the bottom surface of the terminals is exposed and used for surface mounting the semiconductor device package. In some examples, the terminals have flanks or sides exposed that are also coextensive with the package body for additional area for soldering. Example no-lead packages include quad flat no-lead (QFN) packages that are increasingly used, but dual or single sided no-lead packages are used. Small outline no-lead (SON) packages can be used. A microelectronics device package can include leaded packages as well as no-lead packages.

Materials used in packages for microelectronics devices have coefficients of thermal expansion (CTE) which vary with the materials. In an example microelectronics device package, epoxy resin mold compound is used, with copper conductors in a multilayer package substrate. The CTE values for the mold compound and the copper conductors are very different, resulting in a CTE “mismatch.” When materials with different CTE values are used and in particular when the materials are in contact, the different rates of thermal expansion between the materials can cause defects to occur. Defects that occur during manufacture, or under thermal stress during testing or in operation of the devices, are increased when CTE values of materials in contact with one another are very different. When mold compound contacts metal conductors over the device side surface of a package substrate, delamination of the mold compound, and package mold crack defects are observed. As the proportion of the conductor material increases relative to the dielectric material on the device side surface of the multilayer package substrate where mold compound contacts the conductors, the likelihood of these defects also increases.

Methods for forming microelectronics device packages with fewer defects due to thermal stress and CTE mismatch effects, with higher reliability, at relatively low cost, are needed.

### SUMMARY

A described example method includes: forming a device mounting layer on an uppermost trace conductor layer on a device side surface of a package substrate, by performing: forming a device connection conductor layer on the uppermost trace conductor layer, the device connection conductor layer having conductors at locations corresponding to post connect locations on a semiconductor die to be mounted to the device side surface of the package substrate; forming a first layer of dielectric material over and surrounding the conductors of the device connection conductor layer; grinding the first layer of dielectric material to expose the conductors of the device connection conductor layer; patterning device mounting land conductors on the first layer of dielectric material, the device mounting land conductors directly contacting the conductors of the device connection conductor layer, the device mounting land conductors at locations corresponding to the post connect locations on the semiconductor die to be mounted to the device side surface of the package substrate; depositing a second layer of dielectric material over the device mounting land conductors; and grinding the second dielectric layer to expose the device mounting land conductors on the device mounting layer. The uppermost trace layer of the package substrate has a first conductor pattern density that is a ratio of the area of trace conductors of the uppermost trace layer to the surface area of the package substrate, and the device mounting layer has a second conductor pattern density that is a ratio of the area of the device mounting land conductors to the surface area of the device mounting layer, and the second pattern density is less than the first pattern density.

In a further described example, another method includes: providing a strip of unit package substrates having a layer of uppermost trace level conductors on a device side surface, and having connection level conductors and additional trace level conductors in dielectric material, the connection level conductors and additional trace level conductors coupling the uppermost trace level conductors to terminals on a board side surface opposite the device side surface; depositing a device mounting layer on the uppermost trace level conductors, the device mounting layer having device mounting land conductors exposed from a dielectric material on a device mounting surface, and having device connection conductors in the dielectric material coupling the device mounting land conductors to the uppermost trace conductors; flip chip mounting semiconductor dies on the device mounting surface of the device mounting layer by forming solder joints between post connects extending from bond pads on the semiconductor dies and the device mounting land conductors; covering the semiconductor dies and the device mounting surface with mold compound, the mold compound spaced from the uppermost trace conductor layer by the device mounting layer; and cutting through the mold compound, the device mounting layer, and the strip of package substrates in saw streets between the unit package substrates to form the microelectronics device package. The uppermost trace level conductor on the device side surface of the unit package substrates has a first conductor pattern density that is a ratio of the area of the uppermost trace level conductor to the total surface area of the unit package substrate, and the device mounting land conductor on the device mounting layer has a second pattern density that is a ratio of the area of the device mounting land conductors to the total surface area of the unit package substrate; and the first pattern density is greater than the second pattern density.

In another described example, a microelectronics device package includes: a device mounting layer mounted to an uppermost trace conductor layer on a device side surface of a package substrate, the device mounting layer comprising: a device connection conductor layer having conductors in dielectric material, the conductors at locations corresponding to post connect locations on a semiconductor die to be mounted to the device side surface of the package substrate; a device mounting land conductor layer on the device connection conductor layer, the device mounting land conductor layer having device mounting land conductors directly contacting the conductors of the device connection conductor layer, the device mounting land conductors at the locations corresponding to the post connect locations on the semiconductor die; a semiconductor die flip chip mounted to the device mounting layer by solder joints between post connects extending from the semiconductor die and the device mounting land conductors of the device mounting layer; and mold compound covering the semiconductor die, the device mounting layer, and a portion of the package substrate, the mold compound spaced from the uppermost trace conductor layer of the package substrate by the device mounting layer. The uppermost trace layer of the package substrate has a first conductor pattern density that is a ratio of the area of trace conductors of the uppermost trace layer to a surface area of the package substrate, and the device mounting layer has a second conductor pattern density that is a ratio of the area of the device mounting land conductors to the surface area of the device mounting layer, and the second pattern density is less than the first pattern density.

### BRIEF DESCRIPTION OF THE DRAWINGS

FIGS. 1A-1B illustrate, in projection views, a semiconductor wafer with individual semiconductor dies arranged in rows and columns on a device side surface, and an individual semiconductor die from the semiconductor wafer, respectively.

FIGS. 2A-2B illustrate, in projection views, a top side surface and a board side surface, respectively, of a no-lead semiconductor device package that can be used in an arrangement.

FIG. 3 illustrates, in a block diagram, an example circuit that can be used in an arrangement.

FIGS. 4A-4B illustrate, in a series of cross-sectional views, the major steps in manufacturing an example multilayer package substrate that can be used in the arrangements.

FIG. 5 illustrates, in a cross-sectional view, a multilayer package substrate with a device mounting layer on a device side surface that can be used in an arrangement.

FIGS. 6A-6H illustrate, in a series of plan views, the patterns for trace level conductor layers and connection level conductor layers formed in a multilayer package substrate and a device mounting layer used in an example arrangement for a microelectronics device package.

FIGS. 7A-7G illustrate, in a series of cross-sectional views, selected steps for forming a microelectronics device package of an example arrangement.

FIG. 8 illustrates, in a flow diagram, selected steps of a method for forming a device mounting layer for use in the arrangements.

FIG. 9 illustrates, in additional flow diagram, detailed steps for forming microelectronics device packages using the arrangements.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device can be a radio transceiver or a radar transceiver. The semiconductor device can be a receiver or a transmitter. When semiconductor devices are fabricated on a semiconductor wafer and then individually separated from the semiconductor wafer, the individual units are referred to as “semiconductor dies.” A semiconductor die is also a semiconductor device.

The term “microelectronics device package” is used herein. A microelectronics device package has at least one semiconductor die electrically coupled to terminals, and has a package body that protects and covers the semiconductor die. The microelectronics device package can include additional elements. For example, passive components such as capacitors, resistors, and inductors or coils can be included. In some arrangements, multiple semiconductor dies can be packaged together. In some approaches a semiconductor die is mounted to a package substrate that provides conductive leads, a portion of the conductive leads form the terminals for the packaged device. The semiconductor die can be mounted to the package substrate with a device side surface facing away from the substrate and a backside surface facing and mounted to a die pad of the package substrate. In wire bonded device packages, bond wires couple conductive leads of a package substrate to bond pads on the semiconductor die. Alternatively, the semiconductor die can be mounted facing the package substrate using conductive post connects in a flip chip package. The microelectronics device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions can provide the terminals for the microelectronic device package.

The term “package substrate” is used herein. A package substrate is a substrate arranged to receive a semiconductor die and to support the semiconductor die in a completed semiconductor device package. Package substrates useful with the arrangements include conductive lead frames, molded interconnect substrates (MIS), partially etched lead frames, pre-molded lead frames (PMLFs), and multilayer package substrates. In some arrangements, a flip chip semiconductor die mount is used, where conductive post connects that extend from bond pads on the semiconductor die are attached by a solder joint to conductive lands on the device side surface of the package substrate. The conductive post connects can be solder bumps or other conductive materials such as copper or gold posts or columns with solder on a distal end. Copper pillar bumps can be used.

The terms “package substrate” and “multilayer package substrate” are used herein. A package substrate is a substrate arranged for mounting electronic components on a device side surface, and having a board side surface opposite the device side surface. Conductors are provided in dielectric material to couple the electronic components to terminals on the board side surface. Examples include laminates such as printed circuit boards, lead frames, pre-molded leadframes (PMLFs) where mold compound is applied to leads of a leadframe, and molded interconnect substrates (MIS). A multilayer package substrate has multiple conductor layers in a dielectric material including trace level conductors, and has connection level conductors extending through the dielectric material between the trace level conductors. In an example arrangement, a multilayer package substrate is formed in an additive manufacturing process. The additive manufacturing process begins by plating a patterned connection level conductors and then covering the connection level conductors with a layer of dielectric material. Grinding or thinning can be performed on the dielectric material to expose portions of top surface of the layer of conductors from the dielectric material. Additional plating layers can be formed to add additional levels of trace level conductors, some of which are trace layers that are coupled to other trace layers in the dielectric materials by connection level conductors, and additional dielectric material can be deposited at each trace layer level and can cover the conductors.

By using the additive or “build-up” manufacturing approach, and by performing multiple plating steps, multiple dielectric formation steps, and multiple grinding steps, a multilayer package substrate can be formed with an arbitrary number of trace level conductor layers and connection level conductor layers between and coupling portions of the trace level conductor layers. In some of the arrangements, the use of a multilayer package substrate enables high current paths through the multilayer package substrate to terminals of a microelectronics device package.

In an example arrangement, a multilayer package substrate includes copper, gold, nickel, palladium, silver, tin or tungsten conductors that are formed by plating, and a thermoplastic material as the dielectric material. Alternative materials that can be plated as the conductors or as an added plating on the conductors include gold, nickel, palladium, tin, and silver. Combinations of metals and alloys of the metals can be used. The connection level conductors between trace level conductor layers can be of arbitrary shapes and sizes and can include rails and pads to couple trace layers to form paths with low resistance for power and high current signals. High current signals for power semiconductor devices can be greater than an ampere and up to tens or hundreds of amperes. Large conductors are used in the arrangements to provide low resistance paths for high current signals. In some arrangements, the multilayer package substrate is formed using additive manufacturing steps that enable large conductor patterns in both trace conductor layers and connection conductor layers, the connection conductor layers extending through dielectric material between the trace conductor layers. Because additive manufacturing using plating allows for arbitrary shapes for the trace conductor and connection conductor layers, large shapes such as rails and rectangular pads can be formed in stacks extending through the multilayer package substrates, providing low resistance, large area vertical conductors for high current signals.

In packaging semiconductor devices and associated components, mold compound may be used in a molding process to partially cover components, to cover a semiconductor die, and to cover the electrical connections from the semiconductor die. This molding process can be referred to as an “encapsulation” process, although some portions of the package substrates are not covered in the mold compound during encapsulation, for example terminals and leads are exposed from the mold compound to enable electrical connections to the packaged device. Encapsulation is often a compressive molding process, where thermoset mold compound such as resin epoxy can be used. A room temperature solid or powdered mold compound can be heated to a liquid state and then molding can be performed by pressing the liquid mold compound into a mold through runners or channels. Transfer molding can be used. Unit molds shaped to surround an individual device may be used, or block molding may be used, to form multiple packages simultaneously for several devices from mold compound. The devices to be molded can be provided in a strip, array or matrix of several, hundreds or even thousands of devices in rows and columns that are then molded together. After the molding process is complete, the individual microelectronic device packages are cut apart from each other in a sawing operation by cutting through the mold compound and package substrate in saw streets formed between the devices. Portions of the package substrate leads can be exposed from the mold compound package to form terminals for the packaged semiconductor device.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel and normal to the length of the strip. When the molded electronic devices are provided in an array of devices in rows and columns, the saw streets include two groups of parallel saw streets, the two groups are normal to each other and the saw will traverse the molded electronic devices in two different directions to cut apart the packaged electronic devices from one another in the array.

The term “quad flat no-lead” (QFN) is used herein for a type of microelectronics device package. A QFN package has conductive leads that are coextensive with the sides of a molded package body, and in a quad package the leads are on four sides. Alternative flat no-lead packages may have leads on two sides or only on one side. These can be referred to as “small outline no-lead” (SON) packages. No-lead semiconductor device packages can be surface mounted to a board using surface mount technology (SMT) processes.

The term “wettable flank” is used herein. In example arrangements, the terminals of a no-lead microelectronics device package are stepped or dimpled on the sides of the terminals at the outside boundary of the device package, so that solder can form a joint on the sides of the terminals as well as the board side surface of the terminals. The use of wettable flanks in surface mounting technology (SMT) processes aids in automated visual inspection (AVI) of the solder joints, as the side of the solder joint is visible from the top view of the microelectronics device package after surface mounting, increasing reliable AVI inspection of boards and modules. In alternative no-lead packages useful with the arrangements, a terminal of a microelectronics device package can be described as having a “non-wettable” flank. These non-wettable flank terminals have sides that are coextensive with the microelectronics device package, and solder does not form joints on the sides of the non-wettable flanks. However, reliable surface mounting of the no-lead packages using terminals with non-wettable flanks is readily achieved, and the process steps for forming the semiconductor device package are slightly simpler than for the packages with wettable flank terminals.

The term “coefficient of thermal expansion” or “CTE” is used herein. The CTE of a material is a coefficient that indicates the amount of expansion the material will exhibit over temperature increases, or the amount of contraction the material will exhibit over temperature decreases. When a semiconductor device, and in particular, a power semiconductor device, is operated and carries current, the temperature within a microelectronics device package housing the semiconductor device will increase, as heat is generated. The materials used to form the microelectronics device package will expand at different rates with temperature increases, depending on the CTE of the materials. Dielectric materials, such as mold compound, thermoplastics, resins, epoxies and plastics, will have CTE's that are more similar to one another than to the CTE's of metals used to form conductor layers. When mold compound is in contact with conductors that have very different CTE's from the mold compound, delamination and mold compound cracking defects can occur as the microelectronic device package heats and cools during device operation, or in testing.

The term “pattern density” is used herein. The ratio of the area of a conductor material on a surface to the total area of the surface is the “pattern density” for the conductor material, with the remaining area in the arrangements being a dielectric material. In an example arrangement, a package substrate has an uppermost trace conductor layer with a first conductor pattern density in a dielectric such as a thermoset epoxy resin mold compound or a thermoplastic. The uppermost trace conductor layer in example arrangements is configured to carry high currents ranging from an ampere to tens or hundreds of amps and the conductor area on the uppermost trace conductor layer can be quite large. In example arrangements, a device mounting layer is formed on the uppermost trace conductor layer, the device mounting layer includes dielectric material surrounding device land conductors for mounting a semiconductor die in a flip chip die mounting configuration. The device mounting layer has device mounting land conductors formed only where a post connect for a flip chip semiconductor die will be mounted, or where a passive component terminal will be mounted. The device mounting layer has a device side surface with a second conductor pattern density that is less than the first conductor pattern density. When a mold compound is used to cover the device mounting layer of an arrangement, the amount of conductor material that is contact with the mold compound is reduced (compared to a package formed without the arrangements), reducing a CTE mismatch between the mold compound and the other materials, and reducing delamination and mold compound cracking defects that can occur in packages formed without the use of the arrangements.

The term “device mounting layer” is used. A device mounting layer is a layer of dielectric material that covers the device side surface and the uppermost conductor layer of a package substrate. The device mounting layer includes device mounting land conductors on a device mounting surface. The device mounting land conductors are exposed from the dielectric material at locations where the conductive post connects of a flip chip mounted semiconductor die, or at locations where the terminals of a passive component, are to be mounted on the device mounting layer. The remaining surface area of the device mounting layer is dielectric material. The device mounting land conductors are coupled by a device connection conductor layer that extends through the dielectric material of the device mounting layer to contact the uppermost conductor layer of the multilayer package substrate.

In example arrangements, a device mounting layer is formed on the uppermost conductor layer on a device side of a package substrate. In a particular example the package substrate is for a power semiconductor device. Package substrates that can be used include additive manufacturing multilayer package substrates, as well as pre-molded leadframes (PMLFs), partially etched pre-molded leadframes, molded interconnect substrates (MIS), and laminate substrates. The conductor pattern density of the exposed device mounting land conductors on the device mounting layer is less than a conductor pattern density of the uppermost conductor layer of the package substrate. The device mounting layer is covered by mold compound when the semiconductor devices and the passive components are molded in an encapsulation molding process. The device mounting layer spaces the mold compound from the uppermost conductor layer of the package substrate, reducing a coefficient of thermal expansion (CTE) mismatch between mold compound and conductor materials that would occur without the use of the arrangements, where the mold compound would directly contact the uppermost conductor layer of the package substrate.

In some example arrangements, the semiconductor die in a microelectronics device package can be a power device, such as a power field-effect-transistor (“power FET”). In an arrangement for a packaged power FET, the terminals that correspond to power and ground, and in some applications, a switch node terminal, can be configured to carry high currents, high currents as used herein are currents in a range from an ampere to tens or hundreds of amps. Terminals that carry high currents can be made larger than terminals that carry control signals at lower currents, for example, the use of the larger terminals reduces resistance and increases performance for high currents. In some examples, terminals carrying a high current can be coupled to multiple bond pads in parallel on the semiconductor die, again to reduce resistance and increase performance. Power supply terminals, switch node terminals, and ground terminals can be coupled to multiple bond pads using the trace level conductors and the connection level conductors in package substrates used with the arrangements.

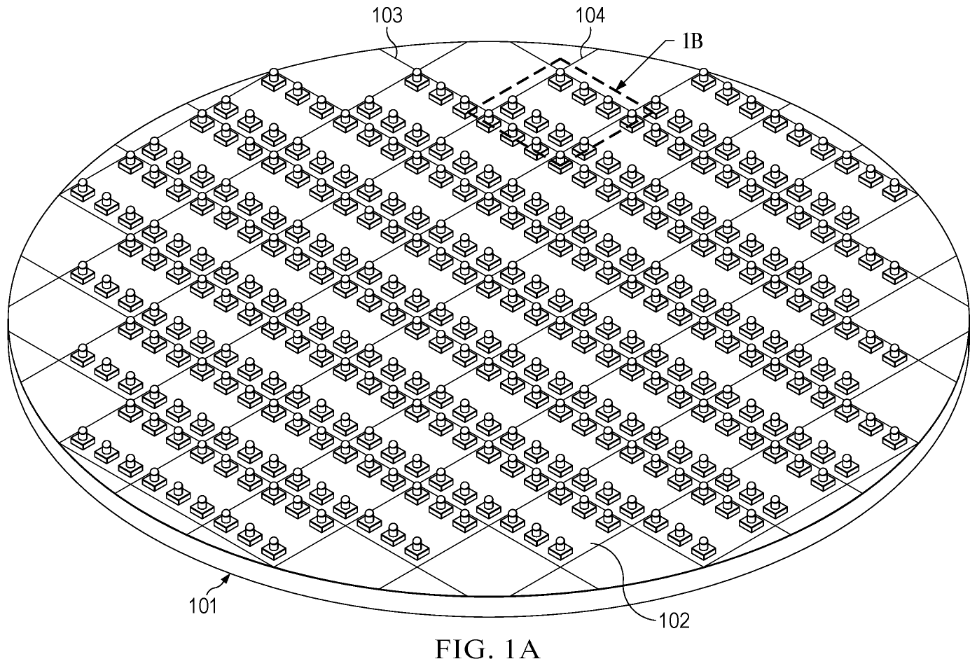

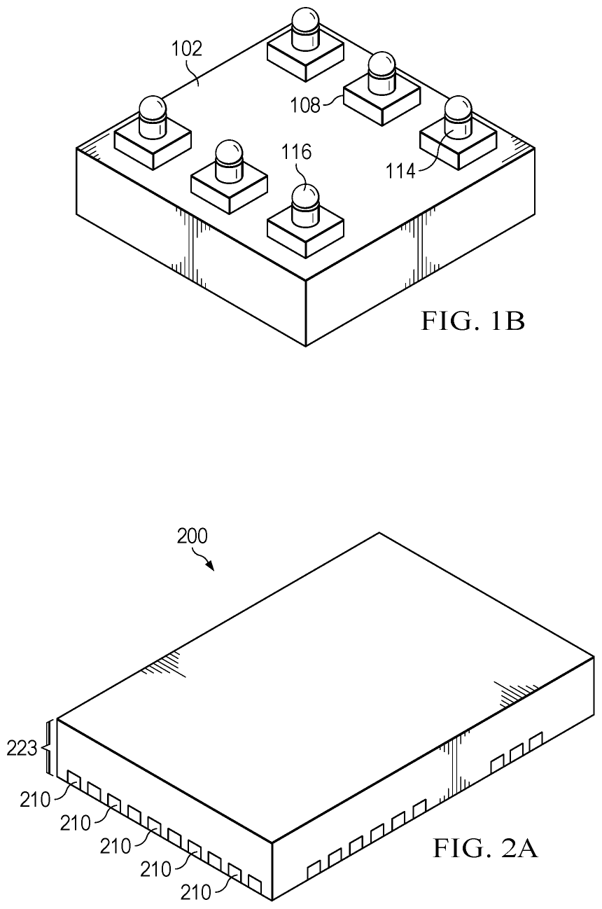

FIGS. 1A and 1B illustrate, in two projection views, a semiconductor wafer having semiconductor dies formed on it, and an individual semiconductor die, respectively. In FIG. 1A, a semiconductor wafer 101 is shown with an array of semiconductor dies 102 formed in rows and columns on a device side surface. The semiconductor dies 102 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 103 and 104, which are perpendicular to one another and which run in parallel groups across the wafer 101, separate the rows and columns of the completed semiconductor dies 102, and provide areas for dicing the wafer 101 to separate the semiconductor dies 102 from one another.

FIG. 1B illustrates a single semiconductor die 102 taken from semiconductor wafer 101. Semiconductor die 102 includes bond pads 108, which are conductive pads that are electrically coupled to devices (not shown) formed in the semiconductor die 102. Not shown for clarity of illustration are under bump metallization (UBM) portions which can be formed over the bond pads to improve plating and adhesion. Materials used in UBM can include nickel, gold, palladium, tin and can be used to reduce tarnish and corrosion and to retard diffusion of metals. Conductive post connects 114 extend from the bond pads 108, and solder 116 is formed on the distal end of the conductive post connects 114. In an example, copper is used for the conductive post connects 114 and the conductive post connects are formed in an electroless or electroplating plating process. The solder 116 can be formed by dropping solder balls and reflowing them on the distal ends of the conductive post connects 114, or by other solder deposition methods.

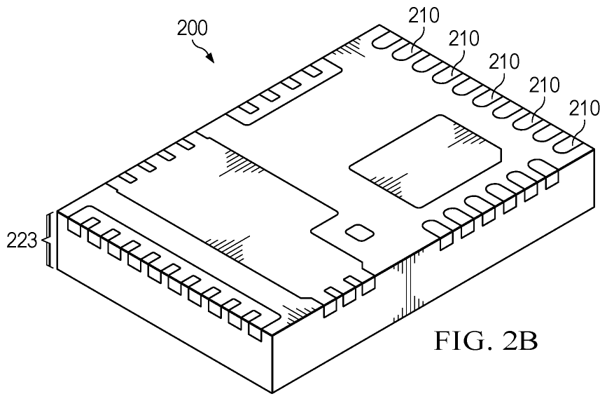

FIGS. 2A-2B are projection views of a no-lead microelectronics device package from a top view, and a board side view, respectively. The microelectronics device package 200 has mold compound 223 covering the surface and protecting devices mounted inside the microelectronics device package (not visible in FIGS. 2A-2B), and terminals 210. In FIG. 2A, the terminals 210, which are shown in an example no-lead configuration with non-wettable flanks, are configured for surface mounting to a system board or module. As shown in the board side view of FIG. 2B, the terminals 210 of the microelectronics device package 200 include large conductors that are coupled to multiple terminals, for power, ground, and high current signal connections to a semiconductor die mounted inside the package 200. In an example arrangement, a power semiconductor die and associated passive components (not visible in FIGS. 2A-2B) are packaged together in microelectronics device package 200. In alternative arrangements, a semiconductor die is packaged without other components. Multiple semiconductor dies can be packaged together, such as a power field effect transistor (power FET) and a controller, or a gate driver, semiconductor die that is coupled to the power FET.

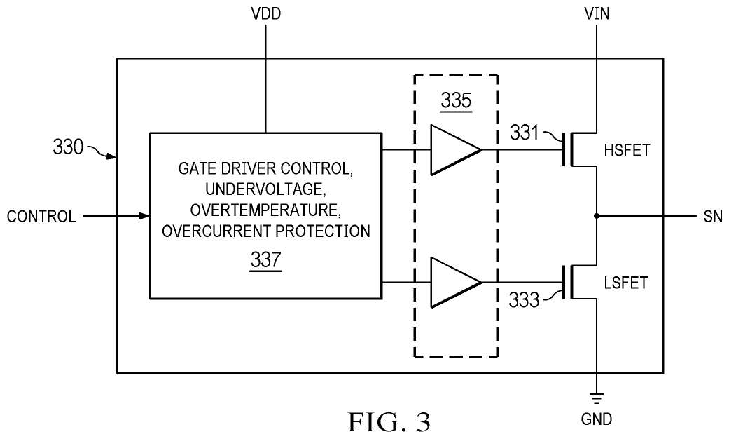

FIG. 3 illustrates, in a block diagram, a circuit schematic for a semiconductor die that can be used in an example arrangement. In FIG. 3, the circuit 330 is for a power semiconductor device that includes two power FET transistors coupled between a power supply terminal labeled “VIN” and a power ground terminal labeled “GND”, and having a switch node terminal labeled “SN” between the two power FETs. In an example, the power FET devices can be silicon metal-oxide-semiconductor (MOS) transistors configured to carry high currents. In one example, NexFET™ technology silicon transistors from Texas Instruments Incorporated can be used. In another example, gallium nitride semiconductor FETs can be used, such as GaNFETs from Texas Instruments Incorporated. When compared to conventional metal-oxide-semiconductor (MOS) FET devices, these power FET devices have increased current carrying capacities, and lower drain-to-source on resistances Rdson, which enable efficient switching power circuits with lower power consumption and less heat, increasing reliability and increasing current carrying capacities for power applications.

The circuit 330 can be used with an external inductor (not shown) coupled to the switch node terminal SN to form a buck converter switching power supply, for example. By applying pulse width modulated gate signals to the high side FET 331, labeled “HSFET”, current is applied from the power supply VIN to the external inductor at the switch node SN for supplying current to a load. By applying alternative pulse width modulated gate signals to the low side FET 333 labeled “LSFET”, excess current from the external inductor can be coupled into the switch node SN to the power ground terminal GND. Using feedback control and current sensing, an output voltage coupled to a load at the external inductor can be closely regulated at various current loads, a desirable characteristic in a switching power supply circuit. The input voltage VIN can vary over a wide range, and by using the control circuitry 337, the output voltage can be regulated to various desirable voltage levels. In an example using NexFET™ power transistors, the current supplied from the voltage supply can be up to over a hundred amperes. The gate drivers 335 are controlled to protect the power FETs from “shoot through” current by ensuring the two power FETs 331, 333 are not both active at the same instant. Overcurrent, overtemperature, current sensing, voltage feedback sensing, and other protective functions can be implemented in the circuit 330 using the control circuits in 337. The use of certain passive components that are packaged together with the semiconductor die, such as bypass capacitors coupled between the input power supply terminal VIN and the ground GND, can increase integration and can reduce system board area or module area that would otherwise be needed to use the devices in a system.

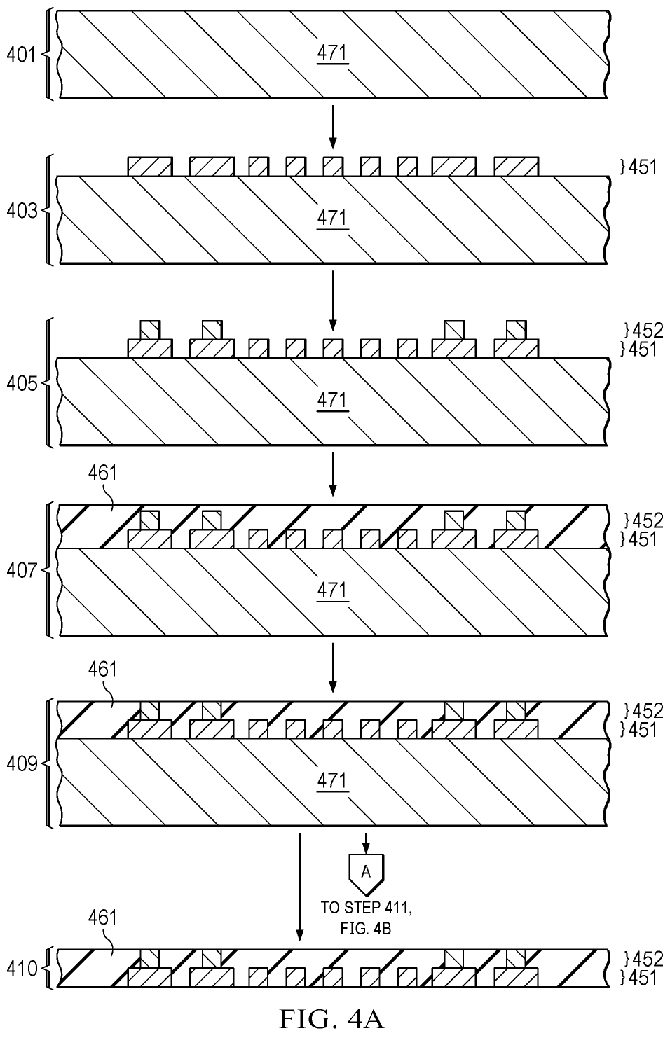

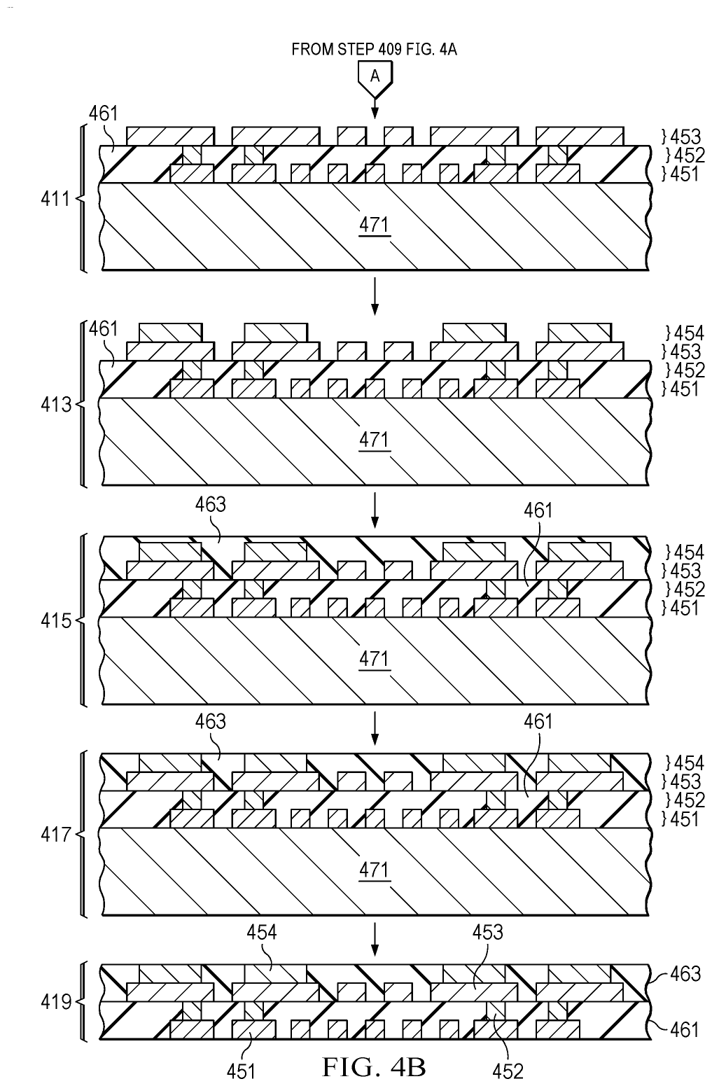

FIGS. 4A-4B illustrate, in a series of cross-sectional views, selected steps for an additive manufacture method for forming an example multilayer package substrate that is useful with the arrangements. Similar additive manufacturing steps can be used to form the device mounting layers of the arrangements. In FIG. 4A, at step 401, a carrier 471 is readied for a plating process. The carrier 471 can be metal, glass, an insulator or a semiconductor material. The carrier 471 can be a substrate where a multilayer conductor layer is needed. The carrier 471 can be cleaned after use and reused in an example process, alternatively, the carrier 471 can be disposed of after the process is complete.

At step 403, a first trace level conductor layer 451 is formed by plating. In an example plating process, a seed layer (not shown) is deposited over the carrier 471, by sputtering, chemical vapor deposition (CVD) or another deposition step. A photoresist layer (not shown for clarity of illustration) is deposited over the seed layer, exposed, developed and cured to form a pattern to be plated. Electroless or electroplating is performed using the exposed portions of the seed layer to start the plating, forming a conductor pattern according to patterns in the photoresist layer. The photoresist layer is removed and the first trace level conductor layer 451 is formed as shown.

At step 405, the plating process continues. A second photoresist layer is deposited, exposed, and developed to pattern a first connection level conductor layer 452. In one example process, by leaving the first photoresist layer in place, the second photoresist layer can be used without an intervening photoresist strip and clean step, to simplify processing. In an example process, the first trace level conductor layer 451 can be used as a seed layer for the second plating operation, to further simplify processing, as another seed layer sputter process is not performed. The first connection level conductor layer 452 acts similarly to a via in a conventional printed circuit board (PCB) or laminate substrate. However, unlike vias used in traditional package substrates such as PCBs, the connection level conductors 452 can be arbitrarily shaped, and when patterned in correspondence with the trace level conductors, rails, tanks, or tubs can be formed in the multilayer package substrate being formed. In the example arrangements, the connection level conductors can form large conductors of various shapes to provide low resistance paths for high current signals in a power device, such as power supplies, ground, or switch node signals.

At step 407, a first dielectric deposition is performed. The first trace level conductor layer 451 and the first connection level conductor layer 452 are covered in a dielectric material 461. In an example a thermoplastic material is used. In a particular example Ajinomoto build-up film (ABF) is used; in alternative examples acrylonitrile butadiene styrene (ABS), acrylonitrile styrene acrylate (ASA), or epoxy resin can be used; resins, epoxies, or plastics can be used. Ajinomoto build-up film (ABF) is commercially available from Ajinomoto Co., Inc., 15-1, Kyobashi 1-chome, Chuo-ku, Tokyo, Japan 104-8315. In an example process for depositing ABF as the dielectric 461, a roll film is laminated onto the trace level conductors 451 and connection level conductors 452. The elements can be heated and a vacuum applied, the ABF softens under heat and conforms to and covers the conductors without voids. The ABF can then be cured to harden to form the dielectric material 461. In an alternative approach, liquid ABF can be applied and cured.

At step 409, a grinding operation is performed on the surface of the dielectric 461 that exposes a surface of the connection level conductor layer 452 and provides conductive surfaces ready for use, or for use in additional plating operations. If the multilayer package substrate is complete at this step, the method ends at step 410, leaving the first trace level conductor layer 451 and the first connection level conductor layer 452 in a dielectric material 461 over the carrier 471.

In examples where additional trace level conductor layers and additional connection level conductor layers are needed, the method continues, leaving step 409 and transitioning to step 411 in FIG. 4B. The multilayer package substrate is shown on carrier 471 with first trace level conductor layer 451 and connection level conductor layer 452.

At step 411, a second trace level conductor layer 453 is formed by plating using the same processes as described above with respect to step 405. A seed layer for the additional plating operation is deposited and a photoresist layer is deposited and patterned, and the plating operation forms the second trace level conductor layer 453 over the dielectric 461, with portions of the second trace level conductor layer 453 electrically connected to the first connection level conductor layer 452.

At step 413, a second connection level conductor layer 454 is formed using an additional plating step on the second trace level conductor layer 453. The second connection level conductor layer 454 can be plated using the second trace level conductor layer 453 as a seed layer, and without the need for removing the preceding photoresist layer, simplifying the process.

At step 415, a second dielectric deposition is performed to cover the second trace level conductor layer 453 and the second connection level conductor layer 454 in a layer of dielectric 463. The multilayer package substrate at this stage has a first trace level conductor layer 451, a first connection level conductor layer 452, a second trace level conductor layer 453, and a second connection level conductor layer 454, portions of the layers are electrically connected together to form conductive paths through the dielectric layers 461 and 463.

At step 417, the dielectric layer 463 is mechanically ground in a grinding process or is chemically etched to expose a surface of the second connection level conductor layer 454. At step 419 the example method ends by leaving the multilayer package substrate on the carrier 471, including the trace level conductor layers 451, 453, and connection level conductor layers 452 and 454 in dielectric layers 461, 463. The steps of FIGS. 4A-4B can be repeated to form multilayer package substrate in arrangements having more layers, by performing plating of a trace level conductor layer, plating of a connection level conductor layer, adding a dielectric material covering the layers, and grinding the dielectric material, repeatedly. In the arrangements, a portion of the conductors forms the terminals for the microelectronics device package.

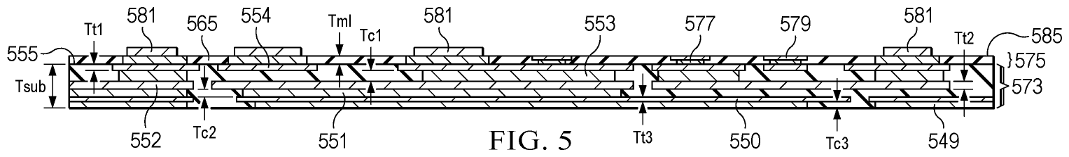

FIG. 5 illustrates, in a cross-sectional view, a multilayer package substrate 573 including a device mounting layer 575 for use in an arrangement. In FIG. 5, multilayer package substrate 573 can be formed using additive manufacturing with plated conductors forming trace level conductors and plated connection level conductors between the trace level conductors, and a dielectric deposited over the conductors at each layer, such as shown in FIGS. 4A-4B and described above. The example multilayer package substrate 573 has three trace level conductor layers 554, 552, and 550, and three connection level conductor layers 553, 551 and 549, with dielectric 561 surrounding the conductors. The additive manufacturing process of FIGS. 4A-4B can be used, for example, where the dielectric is an ABF film and the conductors are electroplated or electroless plated copper or copper alloy. Other conductor materials such as gold, silver, nickel, palladium, and tungsten can be used.

In FIG. 5, the uppermost trace level conductor layer 554 has a device side surface 555 (the top surface of the multilayer package substrate 573 as the elements are shown in FIG. 5). A first connection level conductor layer 553 is shown coupling the uppermost trace level conductor layer 554 to a second trace level conductor layer 552. A second connection level conductor layer 551 is shown coupling the second trace level conductor layer 552 to the third trace level conductor layer 550. The bottommost conductor layer (as the element are arranged in FIG. 5) is a connection level conductor layer 549, which in an example arrangement will form the terminals for a no-lead microelectronics device package. As the multilayer package substrate 573 is arranged in FIG. 5, the uppermost trace level conductor layer 554 is on a device side, where devices will be mounted, and the bottommost connection level conductor layer 549 is on the board side, where the terminals will be formed.

The multilayer package substrate 573 has a total thickness labeled “Tsub”, in an example, of about 220 microns. Other thicknesses can be used depending on the thickness of and the number of conductor layers. In the example, the trace conductor layers 554, 552 and 550, have thicknesses labeled “Tt3”, “Tt2”, and “Tt1” that range between 25 and 45 microns, with a design thickness of 30 microns. The connection conductor layers 553, 551 and 549 have thicknesses labeled “Tc3”, “Tc2”, and “Tc1” between 20 and 45 microns with target thicknesses of 30 and 35 microns. In the example multilayer package substrate 573, the uppermost trace conductor layer 554 has large conductor areas configured for carrying high currents between an ampere and up to hundreds of amperes for a power semiconductor device.

A device mounting layer 575 is formed on the uppermost trace conductor layer 554. The device mounting layer 575 can be formed using a plating and dielectric deposition additive manufacturing process similar to those shown in FIGS. 4A-4B, such as plating copper conductors, and using ABF film to form the dielectric layer 565, and grinding the dielectric layer 565 to expose the conductors. The device mounting layer 575 has a device connection conductors 577, which couple device mounting land conductors 579 to the trace conductor layer 554. In an example, the device mounting layer 575 has a total thickness of about 20 microns, the device connection conductors 577 and the device land conductors 579 each being about 10 microns in thickness. In the arrangements, the device mounting layer 575 has exposed device land conductors 579 only in locations where either a conducive post connect of a flip chip semiconductor die will be solder mounted to the device mounting layer 575, or where a passive component such as a capacitor or resistor will be mounted to the device mounting layer 575. In locations where the passive devices will be mounted, surface mount studs 581 are formed on the device mounting layer 575. The amount of conductor material exposed on the device side surface 585 of the device mounting layer 575 is less than the amount of exposed conductor material on the uppermost trace conductor layer 554. The uppermost trace conductor layer 554 has a first conductor pattern density, which is a ratio of the area of the uppermost trace level conductor material on the device side surface 555 to the total surface area, with the remaining area covered by dielectric. The first conductor pattern density is greater than a second conductor pattern density, which is the ratio of the area of the device land conductors 579 and the surface mount studs 581 on the device mounting surface 585 to the total surface area, with the remaining area covered by dielectric material 565. In one example, the first pattern density of the uppermost trace conductor layer 554 is greater than about 50 percent, while the second pattern density of the device mounting land conductors and the surface mount studs 581 on the device mounting surface 585 is less than 50 percent. When a mold compound is used in a later processing step (described below) to cover the device mounting surface 585, the amount of conductor material that contacts the mold compound is reduced by use of the device mounting layer 575 of the arrangements (when compared to packages formed without the use of the arrangements). Reducing the contact area between the mold compound and the conductor material in the arrangements reduces the amount of CTE mismatch, and reduces or eliminates mold compound cracking and delamination defects that can occur (in packages formed without the use of the arrangements.)

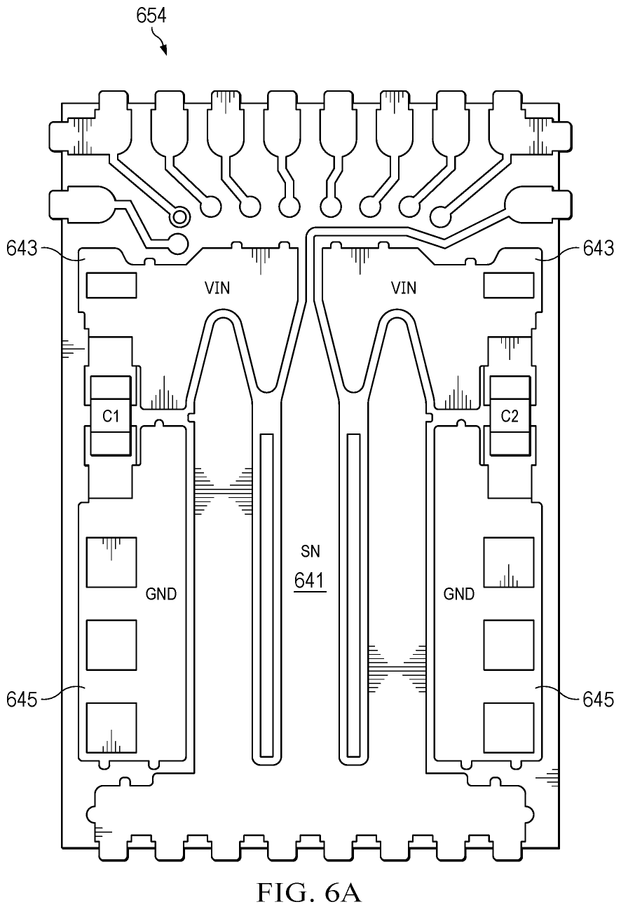

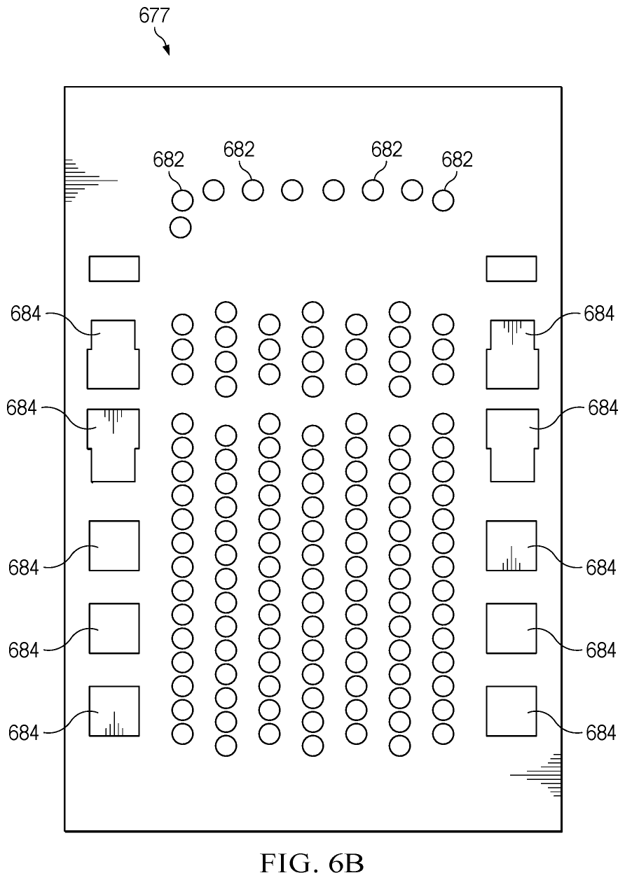

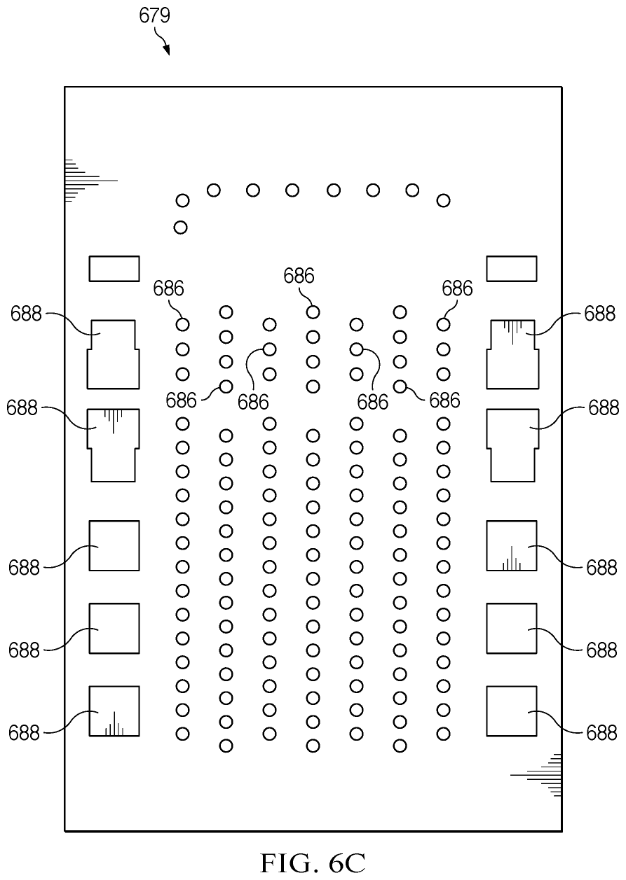

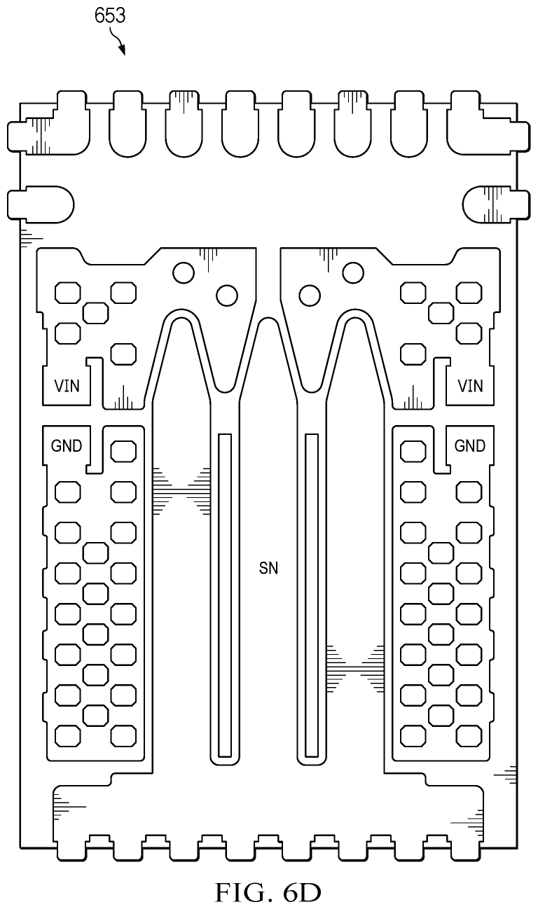

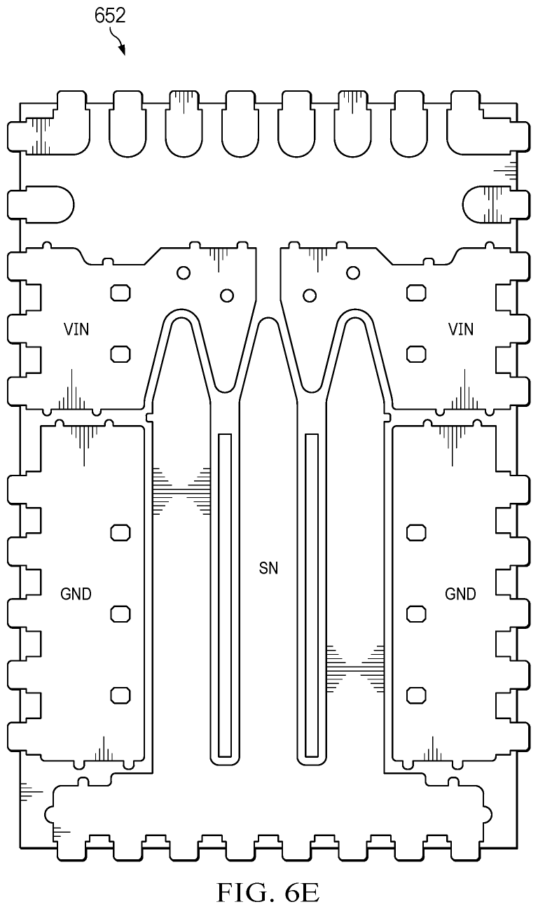

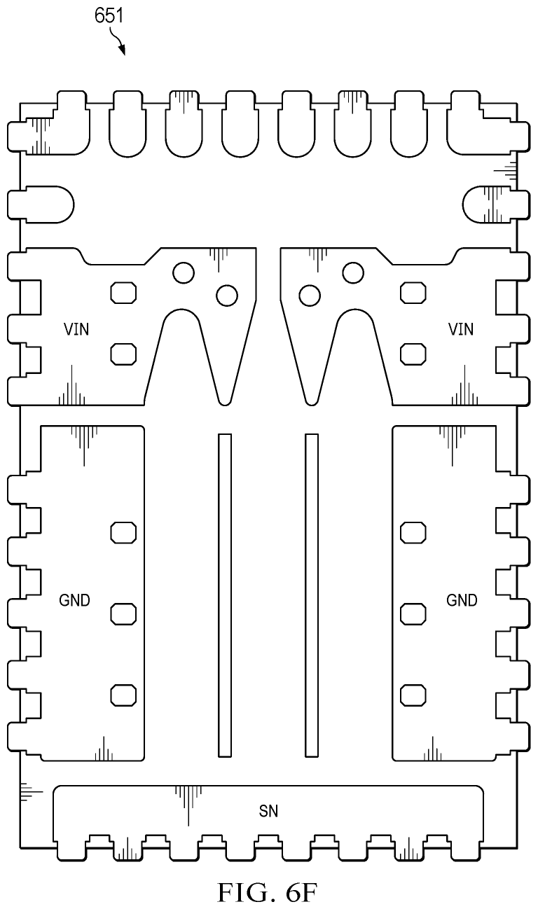

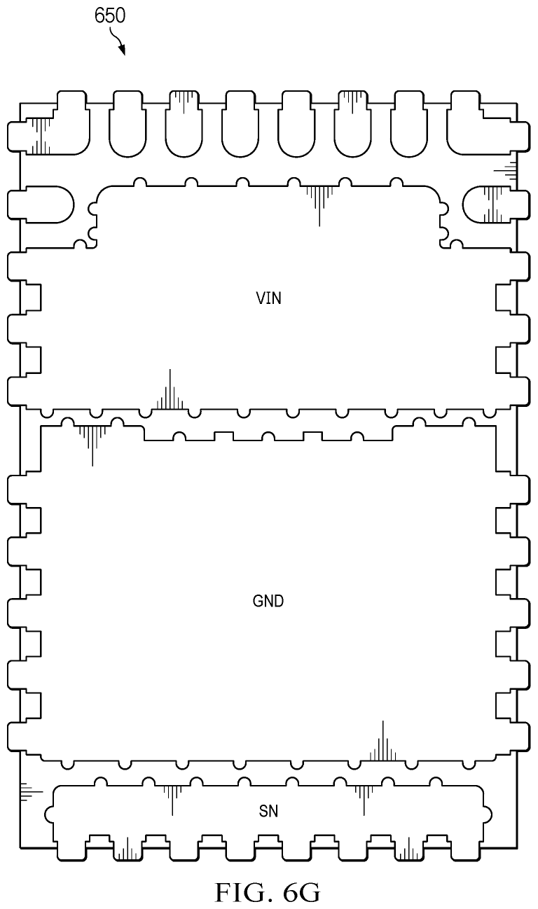

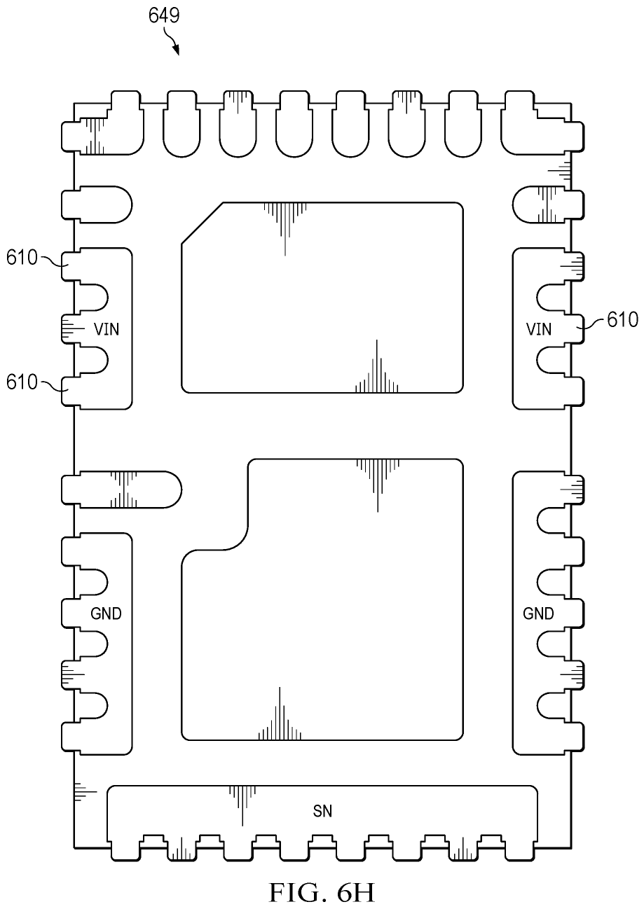

FIGS. 6A-6H illustrate, in a series of plan views, patterns for conductor material at the trace level conductor layers, the connection level conductor layers, and the device mounting layers for an example multilayer package substrate that can be used in an arrangement. By forming these layers in a stack, the terminals for a microelectronics device package are coupled through dielectric materials to a device side surface of the device mounting layer.

FIG. 6A illustrates the pattern of an uppermost trace level conductor layer 654 for a multilayer package substrate to be used with a power semiconductor device. The trace level conductor layer 654 includes portion 641 that is configured to be coupled to a switch node terminal “SN” of a power semiconductor device, portions 643 for coupling to an input power supply terminal “VIN”, and portions 645 configured to be coupled to a power ground supply terminal “GND.” Because these conductor portions 641, 643 and 645 are configured to carry high currents, the area of the conductor material exposed on the uppermost trace level 654 to the total surface area is relatively large, and the conductor pattern density of the trace level conductor layer 654 is also relatively large.

FIG. 6B illustrates, in a plan view, a device connection level conductor layer 677 of a device mounting layer that will be used to couple device mounting land conductors to the uppermost trace layer 654 of FIG. 6A. The device connection level conductor layer 677 includes circular conductors 682, which act as via connections through a dielectric of a device mounting layer, the conductors 682 are located to correspond to the post connects on a semiconductor die to be flip chip mounted on the device mounting layer. The device connection level conductor layer 677 includes rectangular conductors 684 at locations where passive components will be mounted. The device connection conductor layer 677 will be formed on the upper surface of the uppermost trace level conductor layer 654 of FIG. 6A, and the conductors in the device connection level conductor layer will electrically couple to the conductors of the uppermost trace level conductor layer 654 of FIG. 6A. When the additive manufacturing process of FIGS. 4A-4B or a similar “build up” manufacturing process is used to form the device mounting layer, the conductors 682 can be other and various shapes, such as ovals, rectangles, or squares, and while these conductors connect through a dielectric layer in a manner similar to vias in a board, the conductors 682 are not limited to circular or round shapes, unlike vias in PCBs, for example.

FIG. 6C illustrates, in another plan view, a device mounting land conductor pattern 679 for use with the device connection level conductor layer 677 of FIG. 6B. The device mounting land conductor pattern 679 has circular lands 686 corresponding to the locations and sizes of conductive post connects for a semiconductor die, and rectangular lands 688 at locations for the mounting of passive components. In an example, a semiconductor die has 100 micron diameter post connects, with lead free silver-tin-copper (SAC) solder on copper pillars. The circular lands 686 (other shapes can be used in alternative arrangements) are large enough to form lands for flip chip mounting the semiconductor die to the device mounting layer, about 100 microns in diameter, and about 212 microns pitch between the lands. The remaining surface area of the device mounting layer is dielectric. The conductor pattern density of the device mounting land conductor pattern 679 is less than the conductor pattern density of the uppermost trace conductor layer 654 of FIG. 6A. When mold compound is used to cover the devices that will be mounted on the device mounting layer (see device mounting layer 575 in the cross section of FIG. 5, for example) the amount of conductor material that contacts the mold compound is reduced by use of the arrangements (when compared to device packages formed without use of the arrangements) because the device mounting land conductor area is smaller than the uppermost trace conductor area on the package substrate.

FIGS. 6D-6H illustrate, in a series of plan views, the connection level conductor layers and the trace level conductor layers that form the remaining layers of the example multilayer package substrate, which has three trace level conductor layers and three connection level conductor layers. In FIG. 6D, a first connection conductor layer 653 is shown, the uppermost trace level conductor layer 654 (see FIG. 6A) will be formed on the upper surface of the first connection conductor layer 653. FIG. 6E illustrates in another plan view the second trace level conductor layer 652. The first connection level conductor layer 653 (see FIG. 6D) will be formed on this layer, which couples the uppermost trace level conductor layer 654 (see FIG. 6A) to the second trace level conductor layer 652.

In FIG. 6F, a second connection level conductor layer pattern 651 is shown. The second trace level conductor layer 652 (see FIG. 6E) will be formed on this layer 651. In FIG. 6G, a third trace level conductor layer 650 pattern is shown. The second connection level conductor layer 651 (see FIG. 6F) will be formed on this trace level conductor layer 650.

In FIG. 6H, a third connection level conductor layer 649 pattern is shown, this layer will be the bottommost layer of a multilayer package substrate and forms the terminals 610 for a microelectronics device package that will be formed using the multilayer package substrate. The layer 649 has multiple terminals that will couple to the switch node “SN” (see FIG. 6A, portion 641), the power supply input voltage terminal “VIN” (see FIG. 6A, portion 643) and to the power ground terminal “GND” (see portion 645 in FIG. 6A). By vertically stacking the conductor layers as shown in FIGS. 6H-6D and 6A, a multilayer package substrate (see 573 in FIG. 5, for example) is formed. By placing the device mounting land conductor layer 679 of FIG. 6C and the device connection conductor layer 677 of FIG. 6B on the uppermost trace conductor of FIG. 6A, a device mounting layer (see device mounting layer 575 in FIG. 5) is formed over the multilayer package substrate.

By comparing the first conductor pattern density of the pattern 654 in FIG. 6A, the uppermost conductor layer of the multilayer package substrate, to the second conductor pattern density of the pattern 679 in FIG. 6C, the device mounting land conductors on the device mounting layer that will be contacted with mold compound, it can be seen that the amount of conductor material that will be contacted by mold compound deposited on the device mounting layer (see device mounting layer 575 in FIG. 5) is reduced (when compared to a package formed without the device mounting layer of the arrangements, where the mold compound would then contact the trace level conductor layer 654 of FIG. 6A). Because the dielectric material of the device mounting land conductor layer 679 of FIG. 6C has a CTE much closer to that of epoxy resin mold compound than the CTE of conductors, the amount of CTE “mismatch” is reduced, and under thermal expansion during operation or testing of the packaged device, the likelihood of cracking and delamination of the mold compound is also reduced or eliminated. Example CTE values are 8-9 parts per million/degree-C for electronic mold compound, 7 parts per million/degree-C for Ajinomoto build-up film (ABF), and 17 parts per million/degree-C for copper conductors. Because the CTE parameters for mold compound and dielectric material are close in value, while the CTE parameters for mold compound and copper conductors are far apart, the more contact the mold compound has with dielectric material, instead of the conductor material, the less the resulting mold compound stress. Defects are less likely to occur due to use of the arrangements.

In simulations for an example package formed using the arrangements with the patterns of FIGS. 6A-6H, an improvement of 63% (over prior approaches formed without the arrangements) was observed when the top conductor delamination stress was modeled. Similar improvements were observed when strain energy density was modeled at the top surface of the multilayer package substrate with the device mounting layer, compared to a prior approach formed without use of the arrangements in the same sized and similarly configured package.

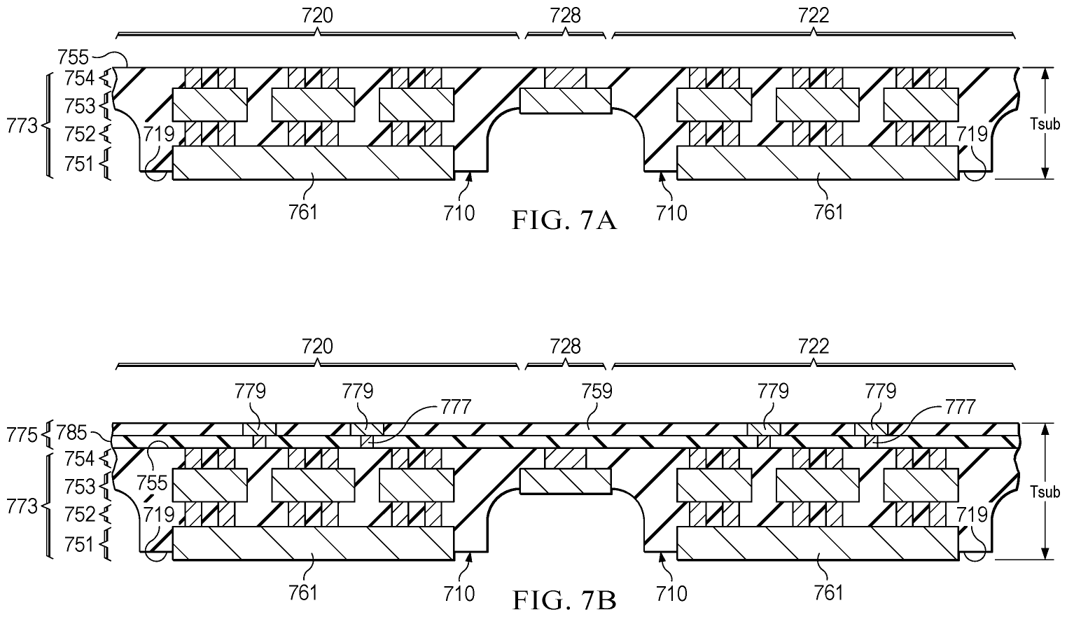

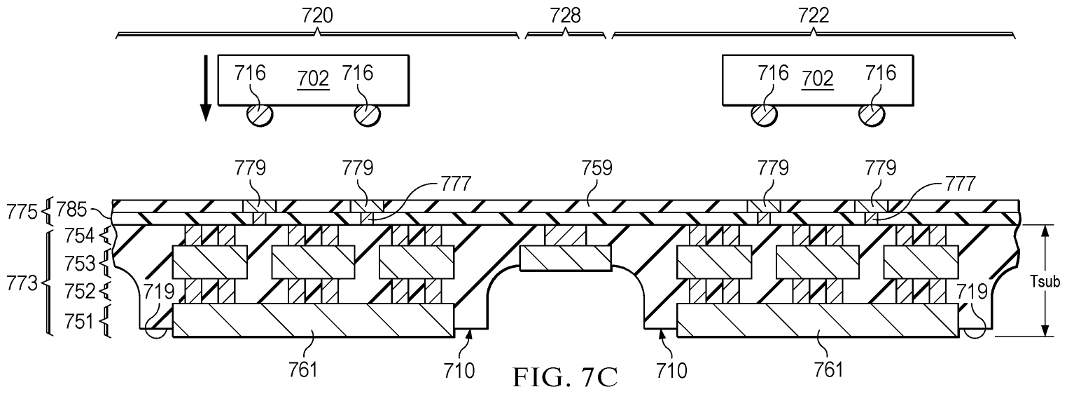

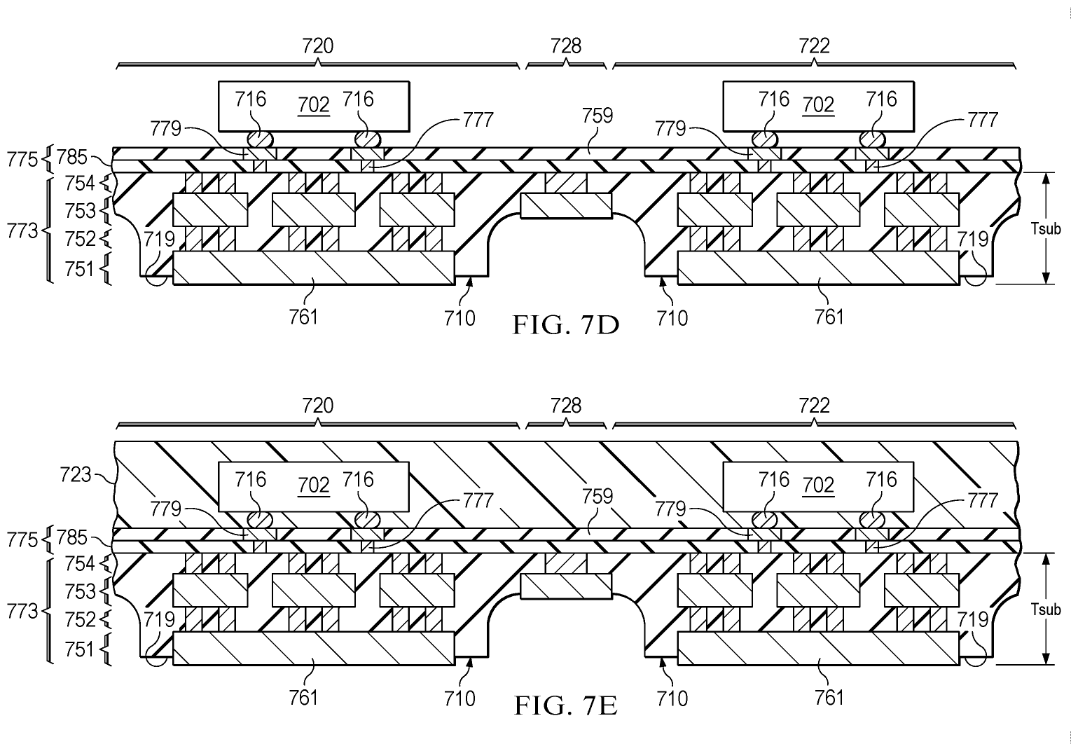

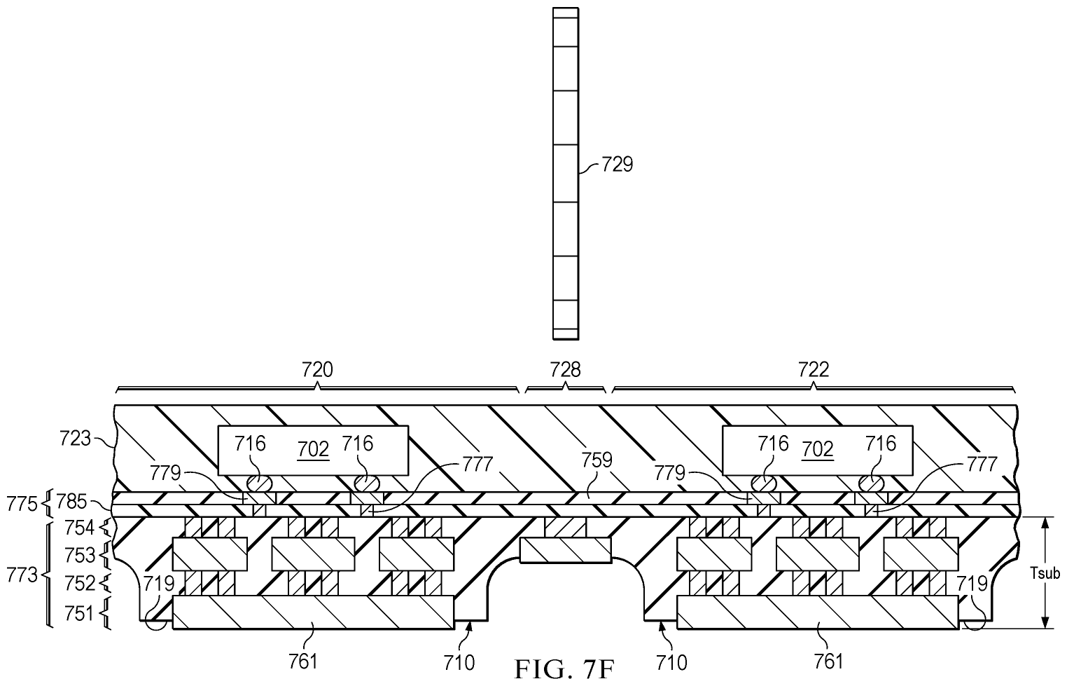

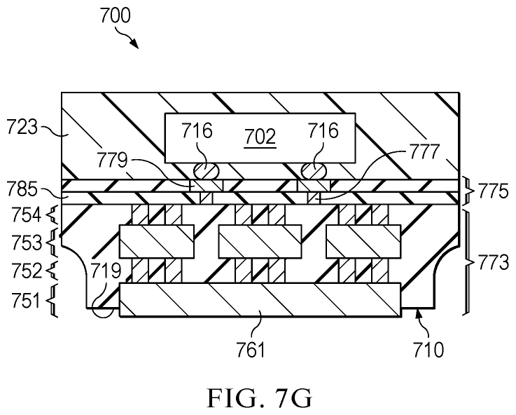

FIGS. 7A-7G illustrate, in a series of cross-sectional views, selected steps used in forming a microelectronics device package of an arrangement.

In FIG. 7A, an alternative package substrate 773 that can be used with the arrangements is shown in a cross-sectional view. The package substrate 773 can be a pre-molded leadframe (PMLF), a laminate, or a molded interconnect substrate (MIS). In FIG. 7A, the illustrated package substrate 773 is a pre-molded leadframe that was formed using partial etching from two sides, and which is provided in a strip or array of unit devices. In the illustrated example, two unit package substrate devices 720, 722 are shown. In a practical example many unit devices can be provided in a grid, array or in strips of the package substrate for parallel processing, to increase throughput of the packaging process. In an example manufacturing process, a partial etching process is used to etch sheet conductor material, such as a copper layer, from two sides. Pre-molding is also done from two sides, to form an uppermost first trace conductor layer 754, and a second trace conductor layer 752, with connection conductor layers 753, 751, extending through dielectric material 761, which can be a mold compound, such as resin epoxy, resin, plastic or epoxy. The conductor layers can be of copper, gold, silver, nickel, palladium, tungsten or other conductor materials, combinations or alloys of these. Plating can be performed on exposed conductor surfaces to increase solderability and reduce tarnish or corrosion. Nickel, palladium, gold and combinations of these can be used as plating layers. Terminals 710 are formed on a board side surface 719. The example package substrate 773 has a thickness “Tsub” of about 200 microns, with the partial etch depths being about 100 microns from either side. Mold compound can be deposited from both sides in molding operations to form pre-mold dielectric 761. The unit devices 720, 722 are spaced by saw streets 728, which provide areas for cutting completed packaged devices apart in a singulation process, described below.

In FIG. 7A, the package substrate 773 includes trace conductor layers 754 and 752, which have horizontal patterns, with the uppermost trace conductor layer 754 on a device side surface 755. The package substrate 773 includes connection conductor layers 753 and 751, which act as via connections through the dielectric 761 between trace conductor layers. The bottommost conductor layer, the connection conductor layer 751, is shaped to form the terminals 710. In the illustrated example, the bottommost conductor layer 751 is etched to form wettable flanks on the terminals 710 by etching the material to form recesses extending beneath the package substrate 773 on the board side surface 719. Wettable flanks in a no-lead microelectronics device package allow solder used in a surface mount technology (SMT) solder mounting operation to form solder joints on the bottom and to wet up the sides of terminals 710. Solder joints formed using wettable flank no-lead packages are visible from a top side view of a system board or module, aiding the use of automated visual inspection (AVI) and of human visual inspection to confirm solder is present.

The package substrate 773, as shown in FIG. 7A, has large conductors on a device side surface 755, with a first conductor pattern density that is a ratio of the area of the exposed conductor material to the total surface area of the package substrate.

FIG. 7B illustrates the package substrate 773 of FIG. 7A after a device mounting layer 775 is formed on the device side surface 755 of the package substrate 773. The device mounting layer 775 includes a dielectric material 759, which can be ABF in an example process, and device connection conductor layer 777, with device land conductor layer 779. In alternative arrangements, additional connection layers and device land conductor layers can be formed using the processes. The device mounting layer 775 on the package substrate 773 can be formed using ABF and plating conductors as described above with respect to FIGS. 4A-4B. The device connection conductor layer 777 connects the device land conductor layer 779 to the device side surface 755 of the package substrate 773 in locations where a semiconductor die will be connected to the uppermost trace conductor layer 754. In one approach the device mounting layer 775 can be formed on the package substrate 773 during manufacture of the package substrate 773. In another approach, the device mounting layer 775 can be formed on a carrier, and then mounted on the package substrate 773.

The device land conductor layer 779 is patterned to have exposed conductive lands only in locations where a semiconductor die or where a passive component will be mounted, with the remaining surface being dielectric material 759. The device land conductor layer 779 has a second conductor pattern density that is the ratio of the exposed device land conductor layer 779 to the total surface area of the device mounting layer 775. The second conductor pattern density is less than the first conductor pattern density because the device land conductor layer 779 only has exposed conductor material where a post connect of the flip chip mounted semiconductor die, or where a passive component, will be mounted.

FIG. 7C illustrates in a cross sectional view the package substrate 773 and the device mounting layer 775 of FIG. 7B, with semiconductor dies 702 being positioned for flip chip die mounting on the device land conductor layer 779 of the device mounting layer 775 for the unit package substrates 720, 722. The semiconductor dies 702 are shown with solder bumps or balls 716 aligned with the device land conductors 779 and being positioned for a solder reflow process. (In the illustrated example, passive components are not visible in the cross-sectional views, but may be mounted to the device mounting layer 775 in areas outside the cross-section).

FIG. 7D illustrates the elements of FIG. 7C after a flip chip die mounting process. The semiconductor dies 702 are mounted on the device side surface of the device mounting layer 775 on the unit package substrates 720, 722. The semiconductor dies 702 are mounted, and electrical connections are made, to the device mounting layer 775 by a solder reflow process that causes the solder 716 on the semiconductor dies 702 to melt and form solder joints to the device land conductors 779 for both unit package substrates 720, 722. By forming device connection conductors 777 that connect through the device mounting layer 775 to the uppermost trace conductor layer 754 of the package substrate 775, and by forming conductors within the package substrate 775 that connect through the dielectric material to the terminals 710 of the bottommost conductor layer 751 of the package substrate, the semiconductor dies 702 are electrically coupled to the terminals 710.

FIG. 7E illustrates the elements of FIG. 7D after a molding process forms a mold compound 723 over the device side surface of the device mounting layer 775. The mold compound 723 can be formed in a transfer molding process where solid molding compound can be heated to a liquid state and forced into a mold holding the package substrate 773, and the mold compound is transferred into the mold covering the device side surface of the device mounting layer 775 and the semiconductor dies 702. The molding process molds the unit package substrates 720, 722 simultaneously, increasing throughput. The mold compound 723 cures to form a solid package body protecting the semiconductor dies 723, and may cover passive components mounted to the device mounting layer 775. Alternative mold processes such as using an epoxy or resin that is liquid at room temperature can be used. In the arrangements such as is shown in FIG. 7E, the mold compound 723 contacts the device side surface of the device mounting layer 775, and the mold compound 723 is spaced from the package substrate 773 by the device mounting layer 775. The device mounting layer 775 has the second conductor pattern density as described above, while the uppermost trace conductor layer 754 has a first conductor pattern density that is greater than the second conductor pattern density. The mold compound 723 is in contact with the dielectric material 785 of the device mounting layer 775 and with small areas of conductor material of the device land conductors 779, but is not in contact with the larger conductors of the uppermost trace conductor layer 754 of the package substrate 775. The use of the arrangements reduces the amount of CTE mismatch between the mold compound 723 and other materials such as large conductors, and reduces the likelihood of mold compound delamination and cracking that can occur in packages formed without the use of the arrangements.

In another aspect of the arrangements, when the molding process takes place, the device mounting layer 775 protects the saw street area 728 from mold compound bleed through, a defect that has been observed in forming packages without the use of the arrangements. By further spacing the mold compound from the saw street areas between the unit package substrates, the possibility the mold compound will erroneously reach the board side surface of the package substrate 773, which is a defect, is also reduced.

FIG. 7F illustrates, in another cross-sectional view, the elements of FIG. 7E, in a sawing operation. A mechanical rotating sawblade 729 is shown, this sawblade traverses the saw streets 728 between the unit package substrates 720, 722 in this example, and cuts through the mold compound 723, the device mounting layer 775, and the package substrate 773, to singulate the completed microelectronics device packages from one another.

FIG. 7G illustrates a microelectronics device package 700 formed after the sawing operation shown in FIG. 7F separates the microelectronic device packages from one another. In the microelectronics device package 700, the mold compound 723 is deposited on and contacts the device mounting layer 775, with the second pattern density for conductors (the device land conductor layer 779). The mold compound is spaced from and does not contact the package substrate 773, with the uppermost trace layer 754 having a first pattern density that is greater than the second pattern density. As a result, the amount of CTE mismatch between the mold compound and other materials is reduced, and the defects that can occur in packages formed without the use of the arrangements, such as mold compound cracking and delamination, are also reduced.

The device mounting layer 775 can be formed using plating and ABF deposition processes as shown in FIGS. 4A-4B, for example, with additive manufacturing steps including sputtering a seed layer, depositing photoresist, patterning the photoresist, plating or electroless deposition of conductor material on the seed layer, depositing the dielectric material over the conductor material, curing the dielectric material, grinding the dielectric material to expose the upper surface of the conductor material, and repeating the steps to form the device connection conductor layer 777 and the device land conductor layer 779 in the dielectric material 785. The dielectric material 785 can be ABF, as described above. Other dielectric materials such as thermoplastics, resins, and epoxies can be used.

The example multilayer package substrate shown in FIG. 5, and the example PMLF package substrate shown in FIGS. 7A-7G, illustrate that the device mounting layer of the arrangements can be used with various package substrate types, including laminate substrates, molded interconnect substrates, and lead frames, as well as the illustrated examples of multilayer package substrates and premolded lead frames. Use of the device mounting layers of the arrangements reduces mold compound stress and reduces the likelihood of defects such as delamination and mold compound cracking in microelectronics device packages. The device mounting layer can be formed on the package substrate, or can be formed separately using a process such as shown in FIGS. 4A-4B and can be applied to the package substrate and mounted on the uppermost trace layer of the package substrate (see FIGS. 7A-7B, device mounting layer 775 is mounted to package substrate 773).

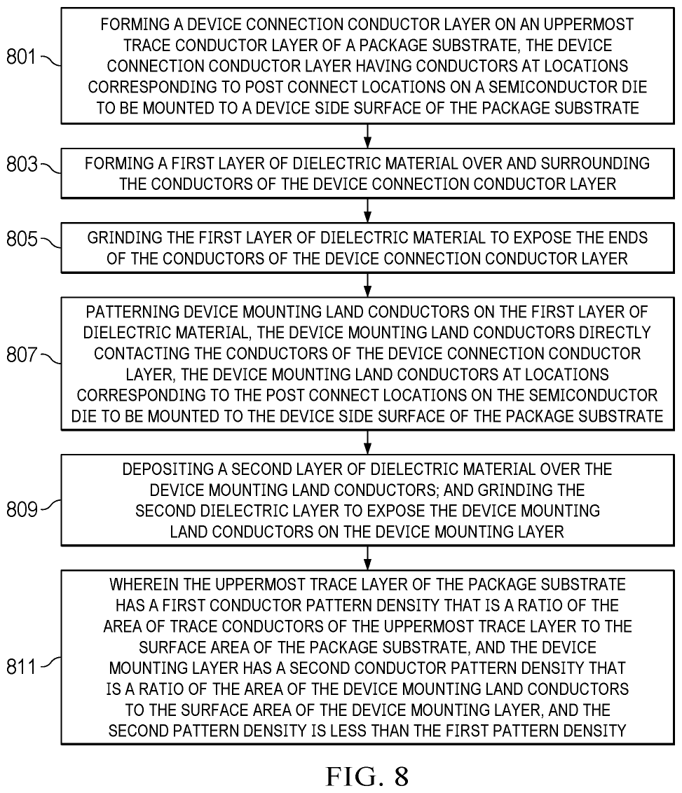

FIG. 8 illustrates, in a flow diagram, major steps for forming a device mounting layer on a package substrate for use in an arrangement. The method begins in step 801 by forming a device connection conductor layer on an uppermost trace conductor layer of a package substrate, the device connection conductor layer having conductors at locations corresponding to post connect locations on a semiconductor die to be mounted to a device side surface of the package substrate. (See the layer 677 in FIG. 6B, which is formed on the layer 654 in FIG. 6A, and see the plating steps shown in FIG. 4A, at step 401, and 403, forming conductors in layers).

At step 803, the method continues by forming a first layer of dielectric material over and surrounding the conductors of the device connection conductor layer. (See dielectric 461 at step 407 of FIG. 4A, where dielectric is deposited over conductors).

At step 805, the method continues by grinding the first layer of dielectric material to expose the ends of the conductors of the device connection conductor layer (see, for example, the grinding step to expose the ends of conductors shown in FIG. 4A at step 409).

At step 807, the method continues by patterning device mounting land conductors on the first layer of dielectric material, the device mounting land conductors directly contacting the conductors of the device connection conductor layer, the device mounting land conductors at locations corresponding to the post connect locations on the semiconductor die to be mounted to the device side surface of the package substrate. (See, for example, the device mounting land conductor pattern 679 in FIG. 6C, and the conductor deposition on the dielectric 461 at FIG. 4B, at step 411).

At step 809, the method continues by depositing a second layer of dielectric material over the device mounting land conductors; and grinding the second dielectric layer to expose the device mounting land conductors on the device mounting layer. (See, for example, 415 and 417 of FIG. 4B, where the second layer of dielectric is deposited over the conductors, and a second grinding step exposes the ends of the conductors on a surface of the dielectric).

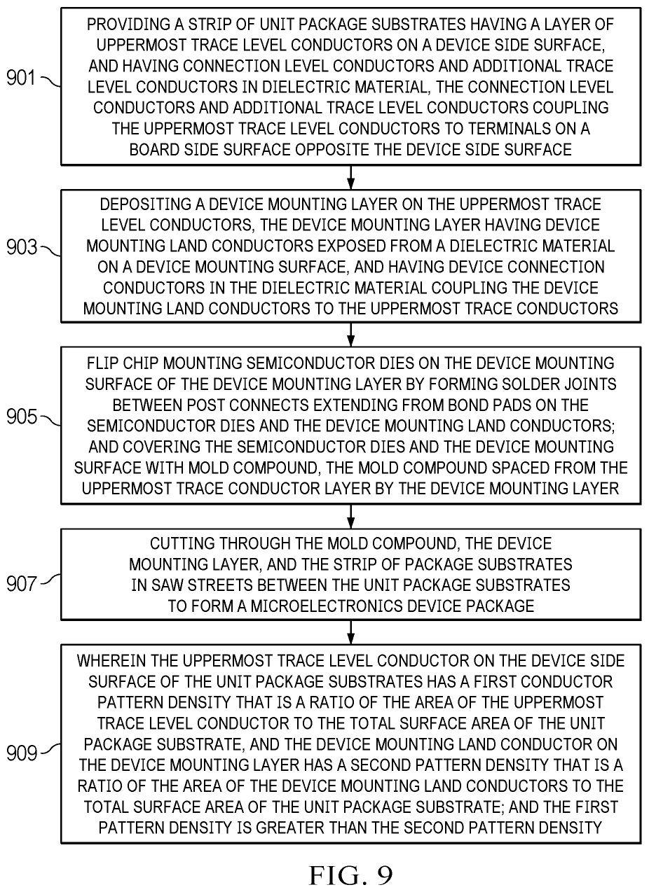

FIG. 9 illustrates, in another flow diagram, selected steps for forming a microelectronics device package including the device mounting layer of the arrangements.

The method of FIG. 9 begins at step 901, by providing a strip of unit package substrates having a layer of uppermost trace level conductors on a device side surface, and having connection level conductors and additional trace level conductors in dielectric material, the connection level conductors and additional trace level conductors coupling the uppermost trace level conductors to terminals on a board side surface opposite the device side surface. (See, for example, the strip of unit package substrates 720, 722 shown in FIG. 7A, with an uppermost layer of trace level conductors 754 and a device side surface 755).

The method continues at step 903, by depositing a device mounting layer on the uppermost trace level conductors, the device mounting layer having device mounting land conductors exposed from a dielectric material on a device mounting surface, and having device connection conductors in the dielectric material coupling the device mounting land conductors to the uppermost trace conductors. (See, for example, FIG. 7B, where device mounting layer 775 is deposited on the trace level conductors 754 on package substrate 773, with dielectric material 785 and conductors 777, 779 in the device mounting layer 775).

The method continues at step 905, by flip chip mounting semiconductor dies on the device mounting surface of the device mounting layer by forming solder joints between post connects extending from bond pads on the semiconductor dies and the device mounting land conductors; and covering the semiconductor dies and the device mounting surface with mold compound, the mold compound spaced from the uppermost trace conductor layer by the device mounting layer. (See FIGS. 7C and 7D, where semiconductor dies 702 are flip chip mounted to the device mounting layer 775, while in FIG. 7E, mold compound 723 is formed over the devices on the device mounting layer).

The method continues in FIG. 9 at step 907, by cutting through the mold compound, the device mounting layer, and the strip of package substrates in saw streets between the unit package substrates to form a microelectronics device package. (See the saw blade 729 in FIG. 7F, and the singulated microelectronics device package 700 in FIG. 7G).

The method concludes at step 909, wherein the uppermost trace level conductor on the device side surface of the unit package substrates has a first conductor pattern density that is a ratio of the area of the uppermost trace level conductor to the total surface area of the unit package substrate, and the device mounting land conductor on the device mounting layer has a second pattern density that is a ratio of the area of the device mounting land conductors to the total surface area of the unit package substrate; and the first pattern density is greater than the second pattern density. (See, for example, the uppermost trace conductor pattern of FIG. 6A, and the device mounting land conductor 679 in FIG. 6C).

The use of the arrangements provides improved microelectronics device packages. A device mounting layer is formed over a package substrate. A semiconductor die, passive components, and/or multiple semiconductor dies and passives are mounted on the device mounting layer. In an example arrangement, an uppermost trace conductor layer on the package substrate has a first conductor density pattern, which is a ratio of the area of trace conductors of the uppermost trace layer to a surface area of the package substrate. The device mounting layer has a second conductor pattern density that is a ratio of the area of the device mounting land conductors to the surface area of the device mounting layer, and the second pattern density is less than the first pattern density. Mold compound formed on the device mounting layer and covering the semiconductor die or dies, and the passive components when used, is spaced from the package substrate by the device mounting layer. Mold compound stress is reduced in the microelectronics device package because the amount of conductor material in contact with the mold compound is reduced by use of the arrangements. Delamination of the mold compound and mold compound cracking defects are reduced or eliminated by use of the arrangements.

Modifications are possible in the described arrangements, and other alternative arrangements are possible within the scope of the claims.

What is claimed is:

1. A method, comprising:
forming a device mounting layer on an uppermost trace conductor layer on a device side surface of a package substrate, by performing:
forming a device connection conductor layer on the uppermost trace conductor layer, the device connection conductor layer having conductors at locations corresponding to post connect locations on a semiconductor die to be mounted to the device side surface of the package substrate;
forming a first layer of dielectric material over and surrounding the conductors of the device connection conductor layer;
grinding the first layer of dielectric material to expose the conductors of the device connection conductor layer;
patterning device mounting land conductors on the first layer of dielectric material, the device mounting land conductors directly contacting the conductors of the device connection conductor layer, the device mounting land conductors at locations corresponding to the post connect locations on the semiconductor die to be mounted to the device side surface of the package substrate;
depositing a second layer of dielectric material over the device mounting land conductors; and
grinding the second layer of dielectric material to expose the device mounting land conductors on the device mounting layer;
wherein the uppermost trace layer of the package substrate has a first conductor pattern density that is the ratio of the area of trace conductors of the uppermost trace layer to the surface area of the package substrate, and the device mounting layer has a second conductor pattern density that is the ratio of the area of the device mounting land conductors to the surface area of the device mounting layer, and the second pattern density is less than the first pattern density.

2. The method of claim 1, and further comprising:
flip chip mounting the semiconductor die having the post connects on the device mounting layer by forming solder joints between the post connects and the device mounting land conductors of the device mounting layer; and
covering the semiconductor die, the device mounting layer, and a portion of the package substrate with mold compound, the mold compound spaced from the uppermost trace conductor layer of the package substrate by the device mounting layer.

3. The method of claim 2, and further comprising:
forming additional conductors in the device connection conductor layer at locations corresponding to the mounting positions of terminals of passive components to be mounted to the uppermost trace layer of the package substrate.

4. The method of claim 3, and further comprising forming additional land conductors in the device mounting land conductor layer corresponding to the mounting positions of terminals of passive components to be mounted to the uppermost trace layer of the package substrate.

5. The method of claim 1, wherein the device land conductors in the device land conductor layer are copper, gold, silver, palladium, tungsten, nickel, alloys or combinations thereof.

6. The method of claim 1, wherein the conductors in the device land conductor layer are copper or copper alloy.

7. The method of claim 1, wherein depositing the first layer of dielectric material and depositing the second layer of dielectric material comprises depositing Ajinomoto build-up film (ABF).

8. The method of claim 1, wherein the depositing the first layer of dielectric material and depositing the second layer of dielectric material further comprises depositing Ajinomoto build-up film (ABF), acrylonitrile butadiene styrene (ABS), acrylonitrile styrene acrylate (ASA), or epoxy resin.

9. The method of claim 1, wherein the package substrate comprises a pre-molded lead frame (PMLF).

10. The method of claim 1, wherein the package substrate comprises a pre-molded lead frame (PMLF), a multilayer package substrate formed using additive manufacturing, a molded interconnect substrate (MIS), or a laminate substrate.

11. The method of claim 1, wherein the package substrate comprises a multilayer package substrate formed using Ajinomoto build-up film (ABF) as a dielectric.

12. The method of claim 1, wherein the first conductor pattern density is greater than 50%.

13. A method for forming a microelectronics device package, comprising:
providing a strip of unit package substrates having uppermost trace level conductors on a device side surface, and having connection level conductors and additional trace level conductors in dielectric material, the connection level conductors and additional trace level conductors coupling the uppermost trace level conductors to terminals on a board side surface opposite the device side surface;
depositing a device mounting layer on the uppermost trace level conductors, the device mounting layer having device mounting land conductors exposed from a dielectric material on a device mounting surface, and having device connection conductors in the dielectric material coupling the device mounting land conductors to the uppermost trace conductors;
flip chip mounting semiconductor dies on the device mounting surface of the device mounting layer by forming solder joints between post connects extending from bond pads on the semiconductor dies and the device mounting land conductors;
covering the semiconductor dies and the device mounting surface with mold compound, the mold compound spaced from the uppermost trace conductor layer by the device mounting layer; and
cutting through the mold compound, the device mounting layer, and the strip of package substrates in saw streets between the unit package substrates to form the microelectronics device package;
wherein the uppermost trace level conductor on the device side surface of the unit package substrates has a first conductor pattern density that is a ratio of the area of the uppermost trace level conductor to the total surface area of the unit package substrate, and the device mounting land conductor on the device mounting layer has a second pattern density that is a ratio of the area of the device mounting land conductors to the total surface area of the unit package substrate; and the first pattern density is greater than the second pattern density.

14. The method of claim 13, wherein depositing a device mounting layer further comprises:
forming the device connection conductors on a carrier, the device connection conductors having conductors at locations corresponding to post connect locations on a semiconductor die to be mounted to a device side surface of the device mounting layer;
forming a first layer of dielectric material over and surrounding the conductors of the device connection conductor layer;
grinding the first layer of dielectric material to expose the ends of the conductors of the device connection conductor layer;
patterning the device mounting land conductors on the first layer of dielectric material, the device mounting land conductors directly contacting the device connection conductors, the device mounting land conductors at locations corresponding to the post connect locations on the semiconductor die to be mounted to the device side surface of the device mounting layer;
depositing a second layer of dielectric material over the device mounting land conductors;
grinding the second dielectric layer to expose the device mounting land conductors on the device mounting layer; and
mounting the device mounting layer on the uppermost trace conductor layer of the package substrates.

15. The method of claim 14, wherein forming the device connection conductors and forming the device mounting land conductors further comprises plating copper or copper alloy.

16. The method of claim 14, wherein depositing the first layer of dielectric material and depositing the second layer of dielectric material further comprises depositing Ajinomoto build-up film (ABF).

17. The method of claim 14, wherein depositing the first layer of dielectric material and depositing the second layer of dielectric material further comprises depositing Ajinomoto build-up film (ABF), acrylonitrile butadiene styrene (ABS), acrylonitrile styrene acrylate (ASA), or epoxy resin.

18. The method of claim 13, wherein providing a strip of unit package substrates comprises providing a pre-molded lead frame (PMLF), a multilayer package substrate formed using additive manufacturing, a molded interconnect substrate (MIS), or a laminate substrate.

19. The method of claim 13, wherein mounting semiconductor dies further comprises mounting power FET semiconductor dies configured to conduct currents of at least one ampere to a switch node terminal.

20. A microelectronics device package, comprising:
a device mounting layer mounted to an uppermost trace conductor layer on a device side surface of a package substrate, the device mounting layer comprising:
a device connection conductor layer having conductors in dielectric material, the conductors at locations corresponding to post connect locations on a semiconductor die to be mounted to the device side surface of the package substrate;
a device mounting land conductor layer on the device connection conductor layer, the device mounting land conductor layer having device mounting land conductors directly contacting the conductors of the device connection conductor layer, the device mounting land conductors at the locations corresponding to the post connect locations on the semiconductor die;
a semiconductor die flip chip mounted to the device mounting layer by solder joints between post connects extending from the semiconductor die and the device mounting land conductors of the device mounting layer; and
mold compound covering the semiconductor die, the device mounting layer, and a portion of the package substrate, the mold compound spaced from the uppermost trace conductor layer of the package substrate by the device mounting layer;
wherein the uppermost trace layer of the package substrate has a first conductor pattern density that is a ratio of the area of trace conductors of the uppermost trace layer to a surface area of the package substrate, and the device mounting layer has a second conductor pattern density that is a ratio of the area of the device mounting land conductors to the surface area of the device mounting layer, and the second pattern density is less than the first pattern density.

21. The microelectronics device package of claim 20, wherein the semiconductor die comprises a power field-effect-transistor (FET) configured to carry at least one ampere of current.

22. The microelectronics device package of claim 21, wherein the conductors of the uppermost trace layer of the package substrate are configured to carry at least one ampere of current.

23. The microelectronics device package of claim 21, wherein the dielectric of the device mounting layer is Ajinomoto build-up film (ABF).

24. The microelectronics device package of claim 21, wherein the semiconductor die is a first semiconductor die, and further comprising a second semiconductor die that is flip chip mounted to the device mounting layer.

25. The microelectronics device package of claim 21, wherein the device mounting layer further comprises surface mount technology stud bumps on the device mounting land conductor layer, the stud bumps at locations where terminals of passive components will be mounted to the device mounting layer.
